(19) United States
(12) Patent Application Publication
(10) Pub. No.: US 2025/0008821 A1
(43) Pub. Date: Jan. 2, 2025

(54) DISPLAY MODULE AND METHOD FOR MANUFACTURING THE SAME, POLARIZER ASSEMBLY, AND DISPLAY APPARATUS

(71) Applicant: XIAMEN TIANMA DISPLAY TECHNOLOGY CO., LTD., Xiamen (CN)

(72) Inventors: Cheng SHI, Xiamen (CN); Yongqiang HAN, Wuhan (CN)

(73) Assignee: XIAMEN TIANMA DISPLAY TECHNOLOGY CO., LTD., Xiamen (CN)

(21) Appl. No.: 18/884,148

(22) Filed: Sep. 13, 2024

(30) Foreign Application Priority Data
Dec. 5, 2023 (CN) 202311661363.5
Mar. 4, 2024 (CN) 202410245166.3

(51) Int. Cl. H10K 59/80

(52) U.S. Cl. CPC H10K 59/873; H10K 59/8791

(57) ABSTRACT

A display module, a polarizer assembly, a method for manufacturing a display module, and a display apparatus. The display module includes a display panel, where a non-active area of the display panel includes a bending area; a polarizer, disposed at a first side of the display panel, where at least a part of the polarizer covers an active area of the display panel; and a protective adhesive layer, disposed at the first side of the display panel, where the protective adhesive layer includes a first protection portion and a second protection portion, the first protection portion covers at least a part of the bending area, the second protection portion is located between the first protection portion and the polarizer, and along a thickness direction of the display panel, a maximum dimension of the second protection portion is less than or equal to a dimension of the polarizer.

The present application claims priority to Chinese Patent Application No. 202311661363.5, titled “DISPLAY MODULE AND PRODUCTION METHOD THEREOF, POLARIZER ASSEMBLY, AND DISPLAY APPARATUS”, and filed on Dec. 5, 2023 with the China National Intellectual Property Administration, and Chinese Patent Application No. 202410245166.3, titled “DISPLAY MODULE AND METHOD FOR MANUFACTURING THE SAME, POLARIZER ASSEMBLY, AND DISPLAY APPARATUS”, and filed on Mar. 4, 2024 with the China National Intellectual Property Administration, which are incorporated herein by reference in their entireties.

### FIELD

The present disclosure relates to the field of display, and in particular to a display module, a method for manufacturing the display module, a polarizer assembly, and a display apparatus.

### BACKGROUND

A narrow bezel of display apparatuses becomes desirable with development of OLED display technology. A means of narrowing the bezel is disposing a binding area of the display panel at a back side of an active area through configuring a bending area. In one embodiment, a driver chip and a flexible circuit board are located at a non-light-emission side of the display panel. The active area the display apparatus can be enlarged, and a width of a bezel can be reduced.

Generally, a protective adhesive layer covering the bending area is provided on the display panel to reduce a breaking risk of metal wires in the bending area.

### SUMMARY

A display module, a method for manufacturing the display module, a polarizer assembly, and a display apparatus are provided according to embodiments of the present disclosure. Bubbles between a cover plate and a polarizer are less likely to form, and final products can have better appearance.

In one embodiment, a display module is provided according to an embodiment of the present disclosure. The display module includes: a display panel, where a non-active area of the display panel includes a bending area; a polarizer, disposed at a first side of the display panel, where at least a part of the polarizer covers an active area of the display panel; and a protective adhesive layer, disposed at the first side of the display panel, where the protective adhesive layer includes a first protection portion and a second protection portion, the first protection portion covers at least a part of the bending area, the second protection portion is located between the first protection portion and the polarizer, and along a thickness direction of the display panel, a maximum dimension of the second protection portion is less than or equal to a dimension of the polarizer.

In one embodiment, another display module is provided according to an embodiment of the present disclosure. The display module includes: a display panel, including an active area and a non-active area; a cover plate, arranged at a first side of the display panel, where an edge of the cover plate exceeds an edge of the display panel when viewed in a direction perpendicular to the display panel; an adhering layer, including a first adhering sub-layer, where the first adhering sub-layer covers at least a side surface at the edge of the display panel; and a sealant layer, including a first sealant sub-layer, where the first sealant sub-layer covers the first adhering sub-layer and covers a surface, which is close to the display panel, of an edge portion of the cover plate, and surface energy of the sealant layer is greater than or equal to surface energy of the adhering layer.

In one embodiment, a polarizer assembly is provided according to an embodiment of the present disclosure. The polarizer assembly includes: a polarizer, a protective film and a non-wetting film, where the protective film is attached to an upper surface of the polarizer, the non-wetting film is disposed on the upper surface of the polarizer in adjacency of a first edge of the polarizer, and a second edge of the non-wetting film is aligned with the first edge when viewed along a thickness direction of the polarizer.

In a fourth aspect, a method for manufacturing a display module is provided according to an embodiment of the present disclosure. The method includes: providing a display panel, where a non-active area of the display panel includes a bending area; providing a polarizer; attaching the polarizer on the display panel, where the pasted polarizer covers an active area of the display panel, and a first side surface of the pasted polarizer is in adjacency of the bending area; providing an adhering layer on the first side surface; and providing a protective adhesive layer on the display panel, where the protective adhesive layer covers at least a part of the bending area, the protective adhesive layer is in contact with the adhering layer, and surface energy of the protective adhesive layer is greater than the surface energy of the adhering layer.

In a fifth aspect, a display apparatus is provided according to an embodiment of the present disclosure, and the display apparatus includes any foregoing display module.

Herein the protective adhesive layer in the display module includes the first protection portion and the second protection portion. The first protection portion covers at least the part of the bending area, and the bending area is protected and metal wires in the bending area is less likely to break. The second protection portion is located between the first protection portion and the polarizer. Along the thickness direction of the display panel, a maximum dimension of the second protection portion is less than or equal to a dimension of the polarizer. In one embodiment, when applying an optical adhesive layer in a subsequent step, the optical adhesive layer can achieve better attachment with an upper surface of the polarizer, which prevents forming a gap between the two. As a result, bubbles are less likely to be formed in the optical adhesive layer, and a yield of final products can be improved.

### BRIEF DESCRIPTION OF THE DRAWINGS

FIG. 1 is a schematic structural diagram of a display module according to an embodiment of the present disclosure.

FIG. 2 is a schematic structural diagram of a display panel according to an embodiment of the present disclosure.

FIG. 3 is a schematic structural diagram of films in a display panel according to an embodiment of the present disclosure.

FIG. 4 is a schematic structural diagram of a display module according to another embodiment of the present disclosure.

FIG. 5 is a schematic structural diagram showing a first angle of a display module as shown in FIG. 4 according to an embodiment of the present disclosure.

FIG. 6 is a schematic diagram of an enlarged structure at portion M as shown in FIG. 5 according to an embodiment of the present disclosure.

FIG. 7 is a schematic diagram of an enlarged structure at portion M as shown in FIG. 5 according to another embodiment of the present disclosure.

FIG. 8 is a schematic structural diagram of a display module in which an angle between a tangent plane of a first surface at a first junction line and a first side surface is greater than or equal to 80° and less than or equal to 100° according to an embodiment of the present disclosure.

FIG. 9 is a schematic structural diagram of a display module according to another embodiment of the present disclosure.

FIG. 10 is a schematic structural diagram showing a first angle of a display module as shown in FIG. 9 according to an embodiment of the present disclosure.

FIG. 11 is a schematic structural diagram of a display module according to another embodiment of the present disclosure.

FIG. 12 is a schematic structural diagram of a display module according to another embodiment of the present disclosure.

FIG. 13 is a schematic structural diagram showing a first sealant sub-layer and a first adhering sub-layer according to an embodiment of the present disclosure.

FIG. 14 is a schematic structural diagram showing a second sealant sub-layer and a second adhering sub-layer according to an embodiment of the present disclosure.

FIG. 13 is a schematic structural diagram showing a first sealant sub-layer and a third adhering sub-layer according to an embodiment of the present disclosure.

FIG. 16 is a schematic diagram of pasting a polarizer assembly on a display panel in a method for manufacturing a display module according to an embodiment of the present disclosure.

FIG. 17 is a schematic diagram of coating a protective adhesive on a display panel in a method for manufacturing a display module according to an embodiment of the present disclosure.

FIG. 18 is a schematic diagram of pasting a polarizer assembly on a display panel in a method for manufacturing a display module according to another embodiment of the present disclosure.

FIG. 19 is a schematic diagram of coating a protective adhesive on a display panel in a method for manufacturing a display module according to another embodiment of the present disclosure.

FIG. 20 is a schematic diagram of providing a display panel in a method for manufacturing a display module according to an embodiment of the present disclosure.

FIG. 21 is a schematic diagram of pasting a polarizer assembly on a display panel in a method for manufacturing a display module according to an embodiment of the present disclosure.

FIG. 22 is a schematic diagram of coating a protective adhesive on a display panel in a method for manufacturing a display module according to an embodiment of the present disclosure.

FIG. 23 is a schematic structural diagram of a top view of a polarizer, an adhering layer, and adhesive strips according to an embodiment of the present disclosure.

FIG. 24 is a schematic structural diagram of a display apparatus according to an embodiment of the present disclosure.

### REFERENCE NUMERALS

| | | | |
|---|---|---|---|
| 1 | Display apparatus | 10 | Display module |
| 100 | Display panel | 101 | Active area |
| 102 | Non-active area | 102a | Fan-out area |
| 102b | Binding area | 103 | Bending area |
| 104 | Light-transmitting via hole | 110 | Substrate |
| 120 | Driving circuit layer | 130 | Light-emitting element |
| 130a | First light-emitting element | 130b | Second light-emitting element |
| 130c | Third light-emitting element | 131 | First electrode |
| 132 | Light-emitting body | 133 | Second electrode |
| 200 | Polarizer | 201 | First edge |
| 210 | Protective film | 211 | Third edge |
| 220 | Non-wetting film | 221 | Second edge |
| 200a | First side surface | 300 | Protective adhesive layer |
| 301 | Protective adhesive | 310 | First protection portion |
| 311 | First section | 312 | Second section |
| 320 | Second protection portion | 320a | First section |
| 320b | Second section | 330 | Adhesive strip |
| 300a | First surface | 300b | First junction line |
| 300c | Second surface | 400 | Cover plate |
| 410 | Ink layer | 411 | First ink edge |
| 500 | Optical adhesive layer | 600 | Back plate |
| 610 | First opening | 620 | Grid adhesive layer |
| 630 | Foam buffer layer | 640 | Heat dissipation copper foil |
| 700 | Adhering layer | 800 | Adhering layer |
| 810 | First adhering sub-layer | 820 | Second adhering sub-layer |
| 830 | Third adhering sub-layer | 811 | First surface |
| 821 | Second surface | 900 | Sealant layer |
| 910 | First sealant sub-layer | 920 | Second sealant sub-layer |
| 911 | First sub-surface | 921 | Second sub-surface |

### DETAILED DESCRIPTION

Hereinafter the present disclosure is described more thoroughly with reference to the drawings to facilitate understanding of the present disclosure. Embodiments of the present disclosure are shown in the drawings. The present disclosure may be implemented in various manners and is not limited to the embodiments described herein. The embodiments are provided to render understanding of the present disclosure more thorough and comprehensive.

All terms and scientific terms used herein have the same meaning appreciated in the art, unless otherwise defined. These terms are intended for describing specific embodiments rather than limiting a scope of the present disclosure. Herein the term “and/or” refers to any one or any combination of the associated objects.

When describe a positional relationship, one element such as a layer, a film, or a substrate “on” another element may be directly on the other element, or there may be an intermediate element between the two, unless otherwise specified. Similarly, one layer “beneath” another layer may be directly beneath the other layer, or there may be an intermediate element between the two. Moreover, one layer “between” two layers may be the only layer between the two layers, or there may one or more other layers between the two layers.

Herein the terms “including”, “having”, and “comprising” does not exclude an additional element that is not listed, unless limitation such as “only”, “consisted of”, etc. is explicitly stated. A singular form of an object may refer to “more than one” such object, and shall not be construed as “only one” such object, unless otherwise defined.

Herein although terms such as “first” and “second” may modify various objects herein, these objects are not limited by these terms. The terms are used intended for distinguishing one element from another. For example, a first element may be called a second element and the second element may be called as the first element in an alternative case without departing from a scope of the present disclosure.

Although not explicitly described, an element should be interpreted to have a margin of error, and the margin is within an acceptable deviation range with respect to a particular value. For example, the terms “about”, “approximately”, or “substantially” may indicate a range within one or more standard deviations, which is not limited herein.

In addition, the term “schematic diagram of planar arrangement” may refer to a top view of a target object, and the term “schematic diagram of a cross section” may refer to a view of a cross sectional obtained by cutting a target object vertically.

The drawings may not be drawn to a scale of 1:1. A relative dimension among components is schematically depicted in the drawings, which may not be consistent with an actual scale.

In conventional technology, bubbles are likely to be formed in an optical adhesive layer of display apparatuses at a contact region between the polarizer and the protective adhesive layer, which results in a poor appearance of the product. Research of the inventor reveals that the above issue origins from following processing. When manufacturing a display module, the display panel is coated with a liquid protective adhesive, and the protective adhesive are cured to form a solid protective adhesive layer. An amount of the adhesive may be controlled during the coating to control a surface of the adhesive to be not higher than a surface of the polarizer. Nevertheless, when the adhesive has not been fully cured, the adhesive would climb along a side surface of the polarizer onto a side surface of a protective film on the polarizer due to its surface tension under a liquid phase. After being cured, the adhesive forms a steep slope adjacent to the polarizer. When the protective film of the polarizer is subsequently removed, the steep slope would be significantly higher than the surface of the polarizer. Afterwards, the cover plate is attached to the polarizer through bonding of an optical adhesive layer. When being attached, the optical adhesive layer cannot be completely bonded with a surface of both the polarizer and the steep slope, because the steep slope is higher than the surface of the polarizer. In one embodiment, a gap is formed between the optical adhesive layer and neighborhood of the steep slope, and the bubbles are formed due to air left in the gap. The produces thus have a poor appearance.

Herein the inventor proposes a following solution. A display module is provided according to an embodiment of the present disclosure. The display module includes a display panel, a polarizer, and a protective adhesive layer. A non-active area of the display panel includes a bending area. The polarizer is disposed at a first side of the display panel, and at least a part of the polarizer covers an active area of the display panel. The protective adhesive layer is disposed at the first side of the display panel, and the protective adhesive layer includes a first protection portion and a second protection portion. The first protection portion covers at least a part of the bending area. The second protection portion is located between the first protection portion and the polarizer. Along a thickness direction of the display panel, a maximum dimension of the second protection portion is less than or equal to a dimension of the polarizer.

Herein the protective adhesive layer in the display module includes the first protection portion and the second protection portion. The first protection portion covers at least the part of the bending area, and the bending area is protected and metal wires in the bending area is less likely to break. The second protection portion is located between the first protection portion and the polarizer. Along the thickness direction of the display panel, a maximum dimension of the second protection portion is less than or equal to a dimension of the polarizer. That is, there is no steep slope in the protective adhesive layer. In one embodiment, when applying an optical adhesive layer in a subsequent step, the optical adhesive layer can achieve better attachment with an upper surface of the polarizer, which prevents forming a gap between the two. As a result, bubbles are less likely to be formed in the optical adhesive layer, and a yield of final products can be improved.

Hereinafter the embodiments of the present disclosure would be described clearly and completely in conjunction with the drawings in embodiments of the present disclosure.

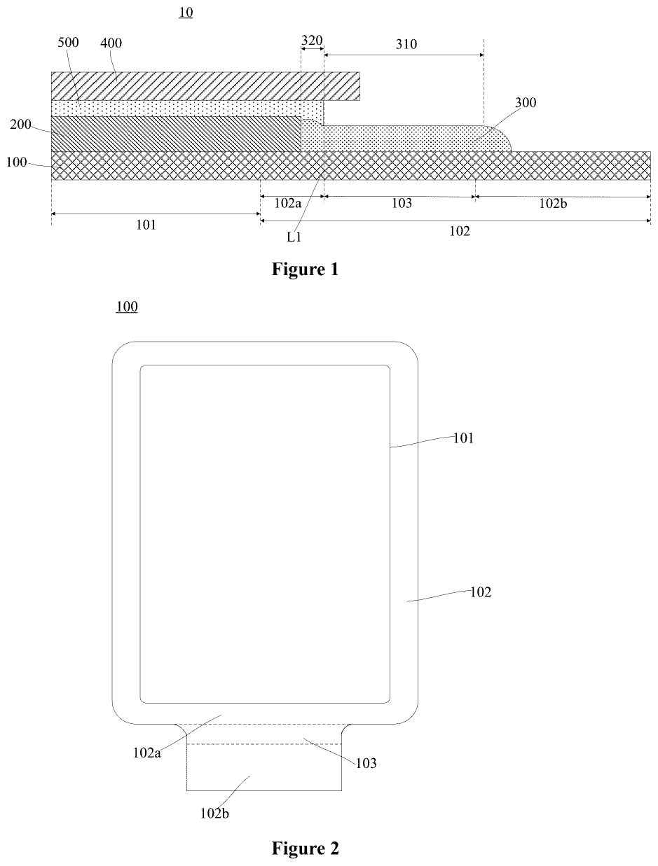

FIG. 1 is a schematic structural diagram of a display module according to an embodiment of the present disclosure, and FIG. 2 is a schematic structural diagram of a display panel according to an embodiment of the present disclosure. As shown in FIG. 1 and FIG. 2, a display module 10 includes a display panel 100, a polarizer 200, and a protective adhesive layer 300. The display panel 100 has a first side and a second side, which are opposite to each other. The display panel 100 includes an active area 101 and a non-active area 102, and the non-active area 102 includes a bending area 103. The polarizer 200 is disposed on the first side of the display panel 100, at least a part of the polarizer covers the active area 101. The protective adhesive layer 300 is disposed on the first side of the display panel 100 and includes a first protection portion 310 and a second protection portion 320. The first protection portion 310 covers at least a part of the bending area 103, and the second protection portion 320 is located between the polarizer 200 and the first protection portion 310. Along a thickness direction of the display panel 100, a maximum dimension of the second protection portion 320 is not greater than a dimension of the polarizer 200.

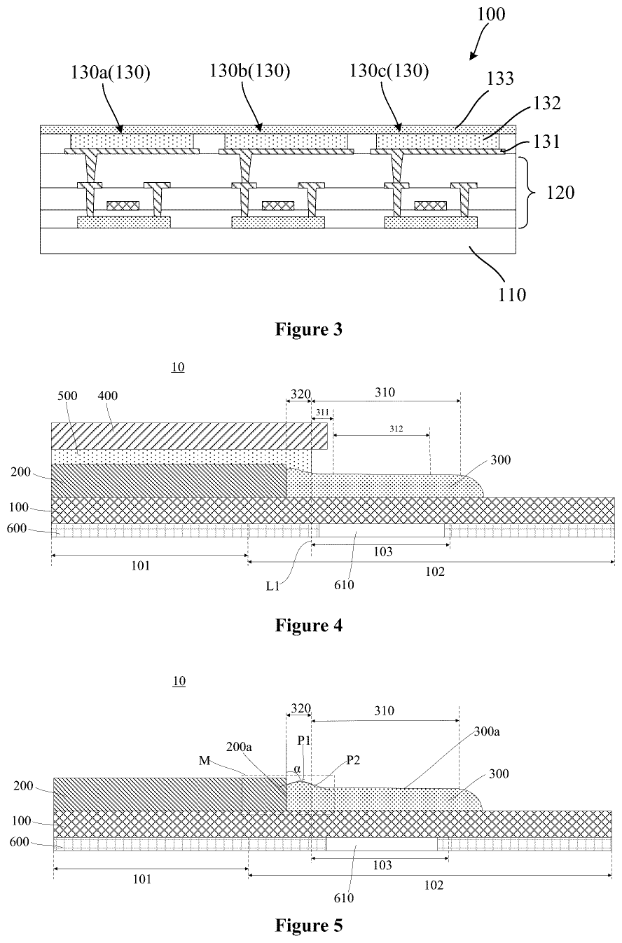

In an embodiment, the display panel 100 may be an organic light-emitting diode (OLED) display panel. FIG. 3 is a schematic structural diagram of films in a display panel according to an embodiment of the present disclosure. As shown in FIG. 3, the display panel 100 may include a substrate 110, a driving circuit layer 120 disposed at a side of the substrate 110, and a group of display layers disposed at a side of the driving circuit layer 120 away from the substrate 110. The substrate 110 may be made of a rigid material, such as glass or silicon, or may be made of a flexible material, such as a metal foil or polymer plastic. The rigid or flexible substrate 110 may be capable to block oxygen and water vapor, and the oxygen, the water vapor, or other contaminants are prevented from diffusing into the display panel 100 via the substrate 110. The group of display layers includes multiple light-emitting elements 130. The multiple light-emitting elements 130 may includes a first light-emitting element 130a for emitting light of a first color, a second light-emitting element 130b for emitting light of a second color, and a third light-emitting element 130c for emitting light of a third color. The first color, the second color, and the third color may be, for example, red, green, and blue. Each light-emitting element 130 may correspond to a sub-pixel of the display panel 100. The light-emitting element 130 may include a first electrode 131, a light-emitting body 132 disposed at a side of the first electrode 131 away from the driving circuit layer 120, and a second electrode 133 disposed at a side of the light-emitting body 132 away from the first electrode 131. The first electrode 131 may be an anode, and the second electrode 133 may be a cathode. Since the cathode side is generally a light-emitting side of the light-emitting element 130, the cathode may be a transparent electrode or a translucent electrode, and its material may be indium tin oxide (ITO), indium zinc oxide (IZO), ITO/Ag/ITO, etc. The anode may be a metallic electrode, and its material may be Cr, Pt, Ru, Au, Ag, Mo, Al, W, Cu, etc. The luminescent material of the light-emitting body 132 may be a low-molecular or high-molecular organic material.

As shown in FIG. 2, the non-active area 102 of the display panel 100 includes the bending area 103. The bending area 103 refers to a part of the non-active area that is bendable, that is, the bending area 103 is capable of being bent toward a backlight side of the display panel 100. The bending area 103 is provided to reduce a width of the bezel, and a requirement on a narrow bezel of the display panel 100 can be met. As shown in FIG. 1 and FIG. 2, the non-active area 102 may further include a fan-out area 102a, which is located between the bending area 103 and the active area 101, and a binding area 102b, which is located at a side of the bending area 103 away from the active area 101. Fan-out wires electrically connected with sub-pixels in the active area 101 is disposed in the fan-out area 102a, and metal wires connected with the fan-out wires is disposed in the bending area 103. The metal wires in the bending area 103 is configured to connect the fan-out wires to the binding area 102b.

The polarizer 200 is disposed at the first side of the display panel 100, and at least the part of polarizer 200 covers the active area 101. The polarizer 200 is configured to reduce reflection of external ambient light at the active area 101. At least the part of the polarizer 200 covering the active area 101 indicates that an edge of the polarizer 200 may extend out of a boundary of the active area 101.

As shown in FIG. 1, the edge of the polarizer 200 extends out of the boundary of the active area 101 but does not extend beyond a bending-starting position L1 of the bending area 103. The bending-starting position L1 refers to a position from which the bending area 103 starts. In other words, an orthographic projection of the edge of the polarizer 200 on the display panel 100 is not aligned with the bending-starting position L1, and the bending area 103 does not start from the edge of the polarizer 200. A reason lies in that the protective adhesive layer 300 is located the first side of the display panel 100 and metal wires are located in the bending area 103. In a case that bending starts from the edge of the polarizer 200, there would be no region for adjustment thickness of the protective adhesive layer 300, and hence uniformity of thickness of the protective adhesive layer 300 is poor. In such case, and the metal wires are likely to break during the bending.

Reference is further made to FIG. 1. The protective adhesive layer 300 includes the first protection portion 310 and the second protection portion 320. The part of the first protection portion 310 covers at least the part of the bending area 103, and the second protection portion 320 is located between the polarizer 200 and the first protection portion 310. That is, in horizontal position, the first protection portion 310 corresponds substantially to the bending area 103, and the second protection portion 320 is located between the bending area 103 and the edge of the polarizer 200. The first protection portion 310 covering at least the part of the bending area 103 indicates that a part of the first protection portion 310 corresponds the bending area 103 in position, or the first protection portion 310 covers the bending area 103 completely. In FIG. 1, the first protection portion 310 covers the bending area 103 completely.

A boundary between the first protection portion 310 and the second protection portion 320 may be defined by the bending-starting position L1. That is, along a direction from the polarizer 200 to the protective adhesive layer 300, the second protection portion 320 is located between the edge of the polarizer 200 and the bending-starting position L1 of the bending area 103, and the first protection portion 310 is arranged at a side of the bending-starting position L1 away from the polarizer 200. As shown in FIG. 4, the display module 10 may further include a back plate 600 disposed at the second side of the display panel 100, and the back plate 600 is provided with a first opening 610. The bending-starting position L1 may be located at a side of the active area 101 close to the first opening 610. A distance between the bending-starting position L1 and the polarizer is greater than a distance between the bending-starting position L1 and the first opening 610.

Reference is further made to FIG. 1. In some embodiments, the second protection portion 320 is in direct contact with the polarizer 200. Alternatively, as shown in FIG. 9, the second protection portion 320 may be in indirect contact with the polarizer 200.

Reference is further made to FIG. 1. In some embodiments, the display module 10 further includes a cover plate 400 and an optical adhesive layer 500, and the cover plate 400 is bonded with the polarizer 200 via the optical adhesive layer 500.

In the display module 10 provided herein, the protective adhesive layer 300 includes the first protection portion 310 and the second protection portion 320, and the first protection portion 310 covers at least the part of the bending area 103 to protect the bending area 103. In one embodiment, metal wires are less likely to break in the bending area 103. The second protection portion 320 is dispose between the polarizer 200 and the first protection portion 310. Along the thickness direction of the display panel 100, the maximum dimension of the second protection portion 320 is not greater than the dimension of the polarizer 200. In one embodiment, when the optical adhesive layer 500 is attached in subsequent processing, the optical adhesive layer 500 can be better bonded with an upper surface of both the polarizer 200 and the protective adhesive layer 300, which avoids forming a gap. In one embodiment, bubbles are less likely be formed in the optical adhesive layer 500, and a yield of final products can be improved. In one embodiment, the maximum thickness of the second protection portion 320 is not greater than the thickness of the polarizer 200, that is, the second protection portion 320 is thinned to facilitate adjustment on the thickness of the second protection portion 320. An average thickness of the second protection portion 320 can be adjusted to be more consistent with an average thickness of the first protection portion 310, which improves uniformity of the thickness of the protective adhesive layer 300. Thus, the distance between the bending-starting position of the bending area 103 and the polarizer 200 can be shortened, and a requirement on a narrow bezel of the display module 10 can be met. In one embodiment, the reduced thickness of the second protection portion 320 decreases a stress on the metal wires below the second protection portion 320. Hence, the metal wires in the bending area 103 are less likely to break.

Along the thickness direction of the display panel 100, the maximum thickness of the second protection portion 320 being not greater than the thickness of the polarizer 20 facilitates better attachment between the optical adhesive layer 500 and the upper surface of both the polarizer 200 and the protective adhesive layer 300. As shown in FIGS. 1, 4, 11, and 12, a space between the cover plate 400 and the polarizer 200 may be filled with a part of the optical adhesive layer 500, and another part of the optical adhesive layer 500 is located between the cover plate 400 and the protective adhesive layer 300 and covers the protective adhesive layer 300. Herein positions of the cover plate 400 in the drawings is merely illustrative and does not limit a position of the cover plate 400 in actual product.

In some embodiments, along the thickness direction of the display panel 100, the first protection portion 310 has a first average thickness, and the second protection portion 320 has a second average thickness. The second average thickness is greater than the first average thickness, and a difference between the second average thickness and the first average thickness does not exceed 15% of the first average thickness.

In an embodiment, the first average thickness of the first protection portion 310 refers to a parameter obtained through dividing a volume of the entire first protection portion 310 by an area of an orthographic projection of the first protection portion 310 on the display panel 100. The second average thickness of the second protection sub-portion 320 refers to a parameter obtained through dividing a volume of the entire second protection sub-portion 320 by an area of an orthographic projection of the second protection part 320 on the display panel 100.

Herein the second average thickness of the second protection portion 320 may be greater than the first average thickness of the first protection portion 310, and the second protection portion 320 is located between the bending-starting position L1 of the bending area 103 and the edge of the polarizer 200, that is, the second protection portion 320 would not be bent. In such case, the second protection portion 320 can protect the metal wires below better, bonding performances of the second protection portion 320 are improved, and hence detachment of films attached to the second protection portion 320 are less likely to occur. Moreover, the difference between the second average thickness of the second protection portion 320 and the first average thickness of the first protection portion 310 may not exceed 15% of the first average thickness of the first protection portion. In one embodiment, the reduced thickness difference between the first protection portion 310 and the second protection portion 320 facilitates improving uniformity of the thickness of the protective adhesive layer 300. Thus, the distance between the bending-starting position of the bending area 103 and the polarizer 200 can be shortened, and the requirement on the narrow bezel requirement of the display module 10 can be met. In one embodiment, a difference between stress on the metal wires beneath the second protection portion 320 and stress on the metal wires beneath the first protection portion 310 is reduced, and hence it is less likely that the metal wires break under large variation of the stress.

In some embodiments, the second average thickness is equal to the first average thickness. For example, the second average thickness and the first average thickness are both 50 μm, 60 μm, 70 μm, or the like. Alternatively, the difference between the second average thickness and the first average thickness may be equal to, or within, 10% of the first average thickness. For example, the second average thickness is 55 μm, and the first average thickness is 50 μm. Alternatively, the difference between the second average thickness and the first average thickness may be equal to, or within, 5% of the first average thickness. For example, the second average thickness is 52.5 μm, and the first average thickness is 50 μm. In other embodiments, the above threshold for the difference between the second average thickness and the first average thickness may be 3%, 7%, 8%, or the like, of the first average thickness.

Moreover, a difference between the maximum thickness of the second protection portion 320 and the first average thickness may not exceed 20% of the first average thickness. That is, the difference between the maximum thickness of the second protection portion 320 and the first average thickness of the first protection portion 310 is controlled to be small. In one embodiment, it is prevented that some part of the second protection portion 320 is too thick, and uniformity of thickness of the second protection portion 320 is improved. The second protection portion 320 can thus protect the metal wires below better, the bonding performances of the second protection portion 320 are improved, and detachment of films attached to the second protection portion 320 are less likely.

In some embodiments, the difference between the maximum thickness of the second protection portion 320 and the first average thickness is equal to 20% of the first average thickness. For example, the maximum thickness of the second protection portion 320 is 72 μm, and the first average thickness is 60 μm. Alternatively, the difference between the maximum thickness of the second protection portion 320 and the first average thickness is equal to, or within, 10% of the first average thickness. For example, the maximum thickness of the second protection portion 320 is 55 μm, and the first average thickness is 50 μm. In an embodiment, the above threshold for the difference between the maximum thickness of the second protection portion 320 and the first average thickness may be 15%, 8%, 5%, or the like. of the first average thickness.

Reference is made to FIG. 4. In some embodiments, the display module 10 further include the back plate 600 disposed at the second side of the display panel 100, and the back plate 600 is provided with the first opening 610. An orthographic projection of the first opening 610 on the display panel 100 is located within the orthographic projection of the first protection portion 310 on the display panel 100. The back plate 600 may be configured to support the display panel 100. The first protection portion 310 covers at least the part of the bending area 103, and the bending area 103 is capable of being bent to the backlight side of the display panel 100. In one embodiment, the first opening 610 in the back plate 600, of which the orthographic projection on the display panel 100 is located within the orthographic projection of the first protection portion 310 on the display panel 100, is capable to reduce a stress on the bent bending area 103 and achieve a small bending radius. In one embodiment, the bezel of the display module 10 can be further shrunk.

Reference is made to FIG. 4. In some embodiments, the first protection portion 310 includes a first section 311 and a second section 312. The first section 311 is connected to the second protection portion 320, and the second section 312 is connected to the first section 311. An orthographic projection of the second section 312 on the display panel 100 is located within the orthographic projection of the first opening 610 on the display panel 100. An orthographic projection of the first section 311 on the display panel 100 and the orthographic projection of the first opening 610 on the display panel 100 overlaps. Along a direction pointing from the polarizer 200 to the protective adhesive layer 300, a length of the first section 311 is less than or equal to ⅓ of a length of the second section 312, and uniformity of a thickness of the second section 312 is greater than or equal to 70%.

Herein the first protection portion 310 may include the first section 311 and the second section 312. The first section 311 is connected to the second protection portion 320, that is, the first section 311 is a transition section between the second protection portion 320 and the second section 312. The orthographic projection of the first section 311 on the display panel 100 overlaps partially with the orthographic projection of the first opening 610 on the display panel 100, and the length of the first section 311 does not exceed ⅓ of the length of the second section 312. In one embodiment, the first opening 610 is close to the polarizer 200, and the distance between the bending-starting position L1 and the polarizer 200 of the bending area 103 is shortened, which facilitates meeting the requirement on the narrow bezel of the display module 10. Moreover, the orthographic projection of the second section 312 on the display panel 100 is located within of the orthographic projection of the first opening 610 on the display panel 100, and the uniformity of the thickness of the second section 312 is greater than or equal to 70%. In one embodiment, the second section 312 can provide good protection on the metal wires in the bending area 103. In one embodiment, the thickness uniformity greater than or equal to 70% provides uniform stress distribution in second section 312 under the bending and strong binding strength between the second section 312 and the display panel 100. Hence, detachment between films is less likely to occur, and reliability of the display module 10 is improved.

The uniformity of thickness is calculated through

$$100 \% ( \frac{max - min}{mean} \times 100 \% ) ,$$

where max refers to the maximum thickness of the second section 312, min refers to the minimum thickness of the second section 312, and mean refers to the average thickness of the second section 312. Such parameter represents a degree of variation in thickness of a film, and hence can reflect how uniform the thickness of the second subsection 312 is. Higher uniformity of thickness indicates the film is more uniform in thickness.

Reference is made to FIG. 5. In some embodiments, the protective adhesive layer 300 has a first surface 300a away from the first side of the display panel 100, and the polarizer 200 has a first side surface 200a facing the second protection portion 320. A first angle α is defined as an angle, which opens toward the light-emission side of the display panel 100 and is between a tangent plane of the first surface 300a at the second protection portion 320 and the first side surface 200a. The first angle is greater than or equal to 70° and less than or equal to 120°.

Herein the angle formed by the tangent plane of the first surface 300a at the second protection portion 320 and the first side surface 200a may be defined as the first angle α. The tangent plane of the first surface 300a at the second protection portion 320 may refer to the tangent plane of the first surface 300a at any point in a range of the second protection portion 320. That is, there are multiple such tangent planes of the first surface 300a at the second protection portion 320, the angles formed by all of them, respectively, and the first side surface 200a belong to the first angle α, and each of these angles is greater than or equal to 70° and less than or equal to 120°. In order to facilitate understanding, two tangent planes of the first surface 300a at the second protection portion 320 are illustratively depicted in FIG. 5, and the two tangent planes are denoted as P1 and P2, respectively. The tangent plane P1 and the tangent plane P2 correspond to different positions on the first surface 300a in the second protection portion 320. An angle between the tangent plane P1 and the first side surface 200a and an angle between the tangent plane P2 and the first side surface 200a both belong to the first angle α.

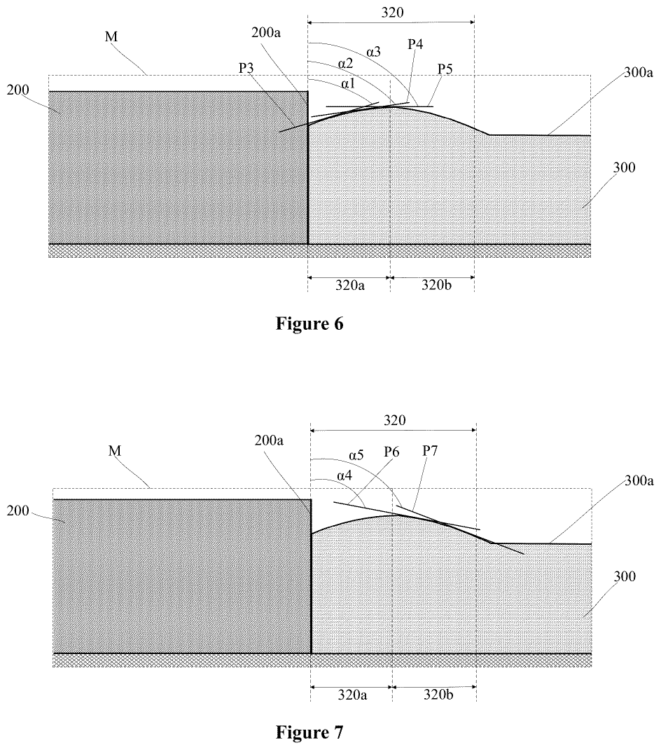

In one embodiment, a shape of the first surface 300a of the protective adhesive layer 300 may be limited through a range of the first angle α. FIG. 6 and FIG. 7 are schematic diagrams of an enlarged structure at portion M as shown in in FIG. 5. As shown in FIG. 6 and FIG. 7, the second protection portion 320 is divided into a first sub-portion 320a and a second sub-portion 320b. The tangent planes of the first surface 300a at two different positions in a range of the first sub-portion 320a are illustratively depicted in FIG. 6, and the two tangent planes are denoted as P3 and P4. The tangent planes P3 and P4 form two first α angles with the first side surface 200a, and the two first α angles are denoted as α1 and α2, respectively. At a junction point between the first sub-portion 320a and the second sub-portion 320b, the tangent plane of the first surface 300a is denoted as P5, and the first angle α between the tangent plane P5 and the first side surface 200a is denoted as α3. In an embodiment, α1 and α2 are both greater than or equal to 70° and less than 90°, and α3 is equal to 90°, which indicates a gradually decrease in the thickness of the first sub-portion 320a gradually in the direction pointing from the protective adhesive layer 300 to the polarizer 200. A rate of such decrease is small, i.e., the surface is substantially flat. The tangent planes of the first surface 300a at two different positions in a range of the second sub-portion 320b are illustratively depicted in FIG. 7, and the two tangent planes are denoted as P6 and P7. The tangent planes P6 and P7 form two first α angles with the first side surface 200a, and the two first α angles are denoted as α4 and α5, respectively. In an embodiment, α4 and α5 are both greater than 90° and less than or equal to 120°, which indicates a gradually increase in the thickness of the second sub-portion 320b in the direction pointing from the protective adhesive layer 300 to the polarizer 200. A rate of such increase is small, i.e., the surface is substantially flat.

In one embodiment, the first angle α between the tangent plane at any point of the first surface 300a in the second protection portion 320 and the first side surface 200a may be controlled to be greater than or equal to 70° and less than or equal to 120°. In such case, the limitation on the first angle α ensures that the thickness of the second protection portion 320 increases and then decreases, or vice versa, at a reasonable rate, that is, the rate of increase and decrease is such small that the thickness of the second protection portion 320 is subject to little variation. In one embodiment, it ensures the thickness uniformity of the second protection portion 320. In one embodiment, the second protection portion 320 applies uniform stress on the metal wires below, and the second protection sub-portion 320 can protect the metal wires better. In one embodiment, the uniform thickness of the second protection portion 320 is capable to facilitate a small distance between the bending-starting position L1 and the edge of the polarizer 200. In one embodiment, the bezel of the display module 10 can be shrunk to meet the requirement on the narrow bezel. In one embodiment, binding strength between the second protection portion 320 and other films is improved. Detachment between the second protection portion 320 and it adjacent film(s) is less likely to occur, and hence water vapor is less likely to invade the active area 101 via a gap generated through the detachment. A service life and reliability of the display module 10 are improved.

The first angle α may range from 75° to 115°. As an example, the first angle α ranges from 85° to 115°. As another example, the first angle α ranges from 80° to 100°.

In an embodiment, the first angle α is greater than or equal to 80° and less than or equal to 100°. In one embodiment, the thickness uniformity of the second protection portion 320 is further improved. In one embodiment, the second protection portion 320 can provide better protection on the metal wires. In one embodiment, the bezel of display module 10 may be further shrunk. In a fourth aspect, the service life and the reliability of the display module 10 can be further improved.

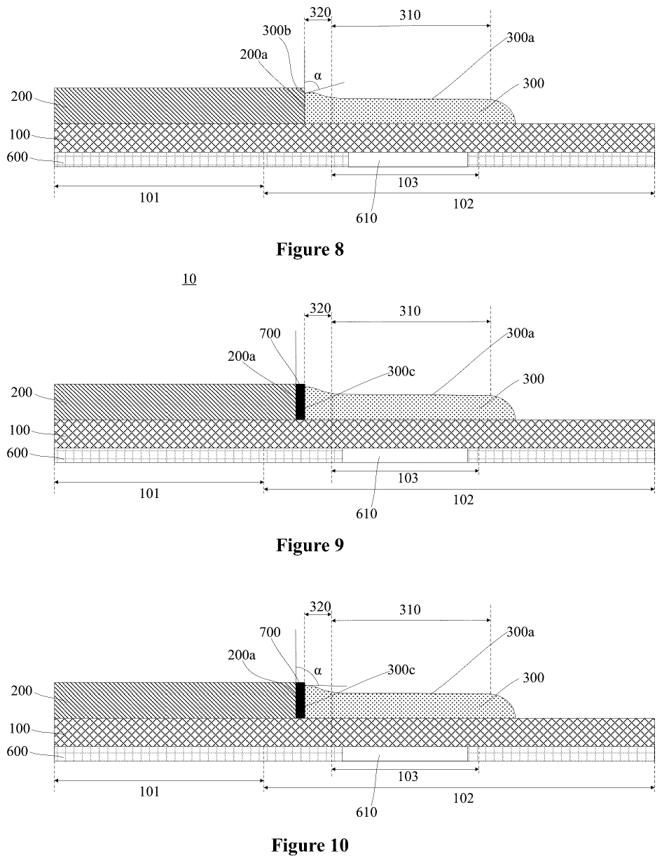

Reference is made to FIG. 8. In an embodiment, the second protection portion 320 of the protective adhesive layer 300 is in contact with the first side surface 200a of the polarizer 200. The first surface 300a and the first side surface 200a contacts at a first junction line 300b, and the first angle α between the tangent plane of the first surface 300a at the first junction line 300b and the first side surface 200a is greater than or equal to 80° and less than or equal to 100°. In one embodiment, it ensures a large contact area between the second protection portion 320 and the first side surface 200a, and hence the second protection portion 320 is less likely to detach from the polarizer 200. In one embodiment, it ensures the second protection portion 320 does not climb onto a top of the polarizer 200 when contacting the first side surface 200a, and the thickness of the second protection portion 320 is smaller than the thickness of the polarizer 200. In one embodiment, bubbles are less likely to be formed in the optical adhesive layer 500 between the cover plate 400 and the polarizer 200, and the yield of final products is improved. In one embodiment, the thickness of the second protection portion 320 is reduced, which facilitates meeting the requirement on the narrow bezel of the display module 10. In one embodiment, the reduced thickness of the second protection portion 320 leads to reduces stress applied by the second protection portion 320 on the metal wires below. Hence, metal wires are less likely to break in the bending area 103.

Reference is made to FIG. 9. In some embodiments, the polarizer has the first side surface 200a facing the second protection portion 320. The display module 100 further includes an adhering layer 700 disposed on the first side surface 200a, the second protection portion 320 is in contact with the adhering layer 700, and surface energy of the protective adhesive layer 300 is greater than surface energy of the adhering layer 700.

Herein the adhering layer 700 may be provided to improve the thickness uniformity of the second protection portion 320 and prevent the second protection portion 320 from forming the steep slope as the conventional technology. As an example, the second protection portion 320 is not in direct contact with the polarizer 200 but adhered to the polarizer 200 through the adhering layer 700. The adhering layer 700 may be a layer of fluorinated liquid, a layer of silica gel layer, etc.

Research of the inventor reveals that the surface energy affects a wetting condition between different substances that contact with each other. The surface energy, also known as surface free energy, refers to excessive energy of molecules at a surface of, for example, the adhering layer 700 or the protective adhesive layer 300, with respect to molecules in the adhering layer 700 or the protective adhesive layer 300. The surface energy may be expressed in unit of J·m, and has a value identical to a value of surface tension. The surface energy of a solid may be measured through the Fowks method, the OWRK method, the ZismanPlot method, the EOS method, or the like. In conventional technology, the protective adhesive layer 300 climbs onto the polarizer 200 mainly due to its surface energy much smaller than the surface energy of the polarizer 200. Specifically, a protective film may be disposed on the upper surface of the polarizer 200 in conventional technology. When the protective adhesive layer 300 in the liquid phase touches the first side surface 200a of the polarizer 200, it extends upward along the first side surface 200a and even reaches an edge of the protective film on the polarizer. When the protective film of the polarizer is removed subsequently, the steep slope is formed in adjacency of the polarizer, and the steep slope is significantly higher than the surface of the polarizer. In such case, the bending operation would be difficult, and the metal wires would be subject to poor protection. Herein the surface energy of the protective adhesive layer 300 may be greater than the surface energy of the adhering layer 700. When the liquid protective adhesive layer 300 touches the adhering layer 700, the surface energy or the surface tension of the protective adhesive layer 300 is greater than that the adhering layer 700, and thus the protective adhesive layer 300 would not extend upward along the adhering layer 700. After the protective adhesive layer 300 is cured, the thickness of the second protection portion 320 would not exceed the thickness of the polarizer 200. Hence, bubbles are less likely to be formed, the thickness uniformity of the protective adhesive layer 300 is improved, and the metal wires are better protected. The requirement on the narrow bezel of the display module 10 can be met.

In some embodiment, a ratio of the surface energy of the adhering layer 700 to the surface energy of the protective adhesive layer 300 is greater than or equal to 0.4 and less than or equal to 0.6. That is, a relationship between the surface energy of the adhering layer 700 and the surface energy of the protective adhesive layer 300 is limited. When the ratio of the surface energy of the adhering layer 700 to the surface energy of the protective adhesive layer 300 is greater than or equal to 0.4 and less than or equal to 0.6, the second protection portion 320 does not climb onto the adhering layer 700. That is, after the protective adhesive layer 300 is cured, the thickness of the second protection portion 320 is not greater than the thickness of the polarizer 200. In one embodiment, bubbles are less likely to be formed, and a yield of final products is improved. In one embodiment, the thickness of the second protection portion 320 is controlled to be small, which facilitates adjustment on the thickness of the second protection portion 320. In one embodiment, the average thickness of the second protection portion 320 can be controlled to approach the average thickness of the first protection portion 310, that is, the thickness uniformity of the protective adhesive layer 300 can be improved. The requirement on the narrow bezel of the display module 10 is also met. In one embodiment, the reduced thickness of the second protection portion 320 leads to smaller stress applied by the second protection portion 320 on the metal wires below. Hence, the metal wires in the bending area 103 are less likely to break. In a fourth aspect, when the ratio of the surface energy of the adhering layer 700 and the surface energy of the protective adhesive layer 300 is greater than or equal to 0.4 and less than or equal to 0.6, the first angle α between the tangent plane of the first surface 300a at any point in the range of the second protection portion 320 and the first side surface 200a of the polarizer 200 can be controlled to be greater than or equal to 70° and less than or equal to 120°. In one embodiment, the thickness uniformity of the second protection portion 320 can be improved, thus the distance between the bending-starting position L1 and the edge of the polarizer 200 can be shortened, and the bezel of the display module 10 can be further shrunk. In addition, binding strength between the second protection portion 320 and other film layers can be improved, and detachment between the second protection portion 320 and adjacent films is less likely to occur. Hence, water vapor is less likely to invade into the active area 101 via the gap generated by the detachment, which improves the service life and the reliability of the display module 10. In an embodiment, the ratio of the surface energy of the adhering layer 700 to the surface energy of the protective adhesive layer 300 may be equal to 0.4, 0.45, 0.5, 0.55, 0.6, or the like.

The surface energy of the protective adhesive layer 300 may determine a type of the protective adhesive layer 300. Therefore, the adhesive may be first selected to obtain the surface energy of the adhesive, then a range of the surface energy of the adhering layer 700 is determined according to the foregoing ratio, and finally the adhering layer 700 having the suitable surface energy is selected for coating on the first side surface 200a of the polarizer 200.

Reference is made to FIG. 9. In some embodiments, the second protection portion 320 has a second surface 300c in contact with the adhering layer 700. Along the direction perpendicular to (i.e., the thickness direction of) the display panel 100, the difference between the maximum dimension (i.e., the maximum thickness) of the second protection portion 320 and a length (i.e., a height) of the second surface 300c does not exceed 20% of the length of the adhering layer 700.

Herein the height of the second surface 300c may be limited, and hence an area of the second surface 300c is limited. When the difference between the maximum thickness of the second protection portion 320 and the height of the second surface 300c does not exceed 20% of the height of the adhering layer 700, the height of the second surface 300c is close to the maximum thickness of the second protection portion 320, and the area of the second surface 300c is not too small. In one embodiment, the contact area between the second protection portion 320 and the adhering layer 700 is large enough to ensure binding strength between the second protection portion 320 and the adhering layer 700. Detachment between the two is less likely to occur during the bending.

In an embodiment, the height of the adhering layer 700 and the thickness of the polarizer 200 may be identical, for example, may be equal to 105 μm, and the maximum thickness of the second protection sub-portion 320 does not exceed the thickness of the polarizer 200, for example, may be equal to 90 μm. When the difference between the maximum thickness of the second protection portion 320 and the height of the second surface 300c is equal to 20% of the height of the adhering layer 700, the height of the second surface 300c may be 69 μm. When the difference between the maximum thickness of the second protection portion 320 and the height of the second surface 300c is equal to 10% of the height of the adhering layer 700, the height of the second surface 300c may be 79.5 μm. In the above cases, the area of the second surface 300c is large enough to ensure the binding strength between the protective adhesive layer 300 and the adhering layer 700 and avoid detachment between the layers during the bending.

Reference is made to FIG. 10. In some embodiments, the protective adhesive layer 300 has the first surface 300a away from the first side of the display panel 100, and the polarizer 200 has the first side surface 200a facing the second protection portion 320. The first angle α is formed between the tangent plane of the first surface 300a at the second protection portion 320 and the side surface 200a, and the first angle α opens toward the light-emission side of the display panel 100. The first angle α is greater than or equal to 80° and less than or equal to 100°.

Herein the tangent plane of the first surface 300a at the second protection portion 320 refers to the tangent plane at any point of the first surface 300a in the range of the second protection portion 320. That is, there are multiple tangent planes of the first surface 300a at the second protection portion 320, the multiple tangent planes form multiple first angles α, respectively, with the first side surface 200a, and each first angle α is greater than or equal to 80° and less than or equal to 100°.

In other words, a shape of the first surface 300a of the protective adhesive layer 300 with the adhering layer 700 may be limited. Specifically, the first angle α between the tangent plane at any point of the first surface 300a in the range of the second protection portion 320 and the first side surface 200a may be greater than or equal to 80° and less than or equal to 100°. Such limitation ensures that the thickness of the second protection portion 320 increases and then decreases, or the vice versa, at a reasonable rate along the direction pointing from the protective adhesive layer 300 to the polarizer 200. That is, the increase and the decrease are slow, and the thickness of the second protection portion 320 is subjection to small variations. In one embodiment, the thickness uniformity of the second protection portion 320 can be improved. In one embodiment, the second protection portion 320 can provide better protection on the metal wires. In one embodiment, the bezel of the display module 10 can be further shrunk. In a fourth aspect, the service life and the reliability of the display module 10 can be further improved.

In some embodiments, along the direction perpendicular to the display panel 100, the polarizer 200 has a first thickness, the adhering layer 700 has a first height, the first height is less than or equal to the first thickness, and the maximum thickness of the second protection portion 320 is less than or equal to the first height. In one embodiment, it is prevented that the thickness of the adhering layer 700 exceeds the polarizer 200. Hence, when binding the optical adhesive layer 500 in a subsequent process, the optical adhesive layer 500 can be better attached to the upper surface of both the polarizer 200 and the protective adhesive layer 300 without a gap. Bubbles are less likely to be formed in the optical adhesive layer 500, and the yield of final products can be improved. In one embodiment, the thickness of the second protection portion 320 within an appropriate range facilitates further reduction in the stress applied by the second protection portion 320 on the metal wires below. Hence, the metal wires are less likely to break.

In an embodiment, the first height of the adhering layer 700 and the first thickness of the polarizer 200 are identical, for example, may be equal to 105 μm, 106 μm, or the like. The maximum thickness of the second protection portion 320 may be equal to 100 μm, 90 μm, 70 μm, or the like.

In some embodiments, along the thickness direction of the display panel 100, the minimum dimension of the protective adhesive layer 300 is greater than or equal to ⅓ of the thickness of the polarizer 200, and the maximum thickness is less than or equal to the thickness of the polarizer 200. For example, the thickness of the polarizer 200 ranges from 105 μm to 106 μm. Taking 105 μm as an example, the minimum thickness of the protective adhesive layer 300 may be equal to 35 μm, and the maximum thickness of the protective adhesive layer 300 may be equal 105 μm. In one embodiment, the thickness of the protective adhesive layer 300 is subject to small variations. In one embodiment, the thickness uniformity of the protective adhesive layer 300 can be improved. In one embodiment, the protective adhesive layer 300 can provide better protection on the metal wires. In one embodiment, the bezel of the display module 10 can be further shrunk. In a fourth aspect, the service life and the reliability of the display module 10 can be further improved.

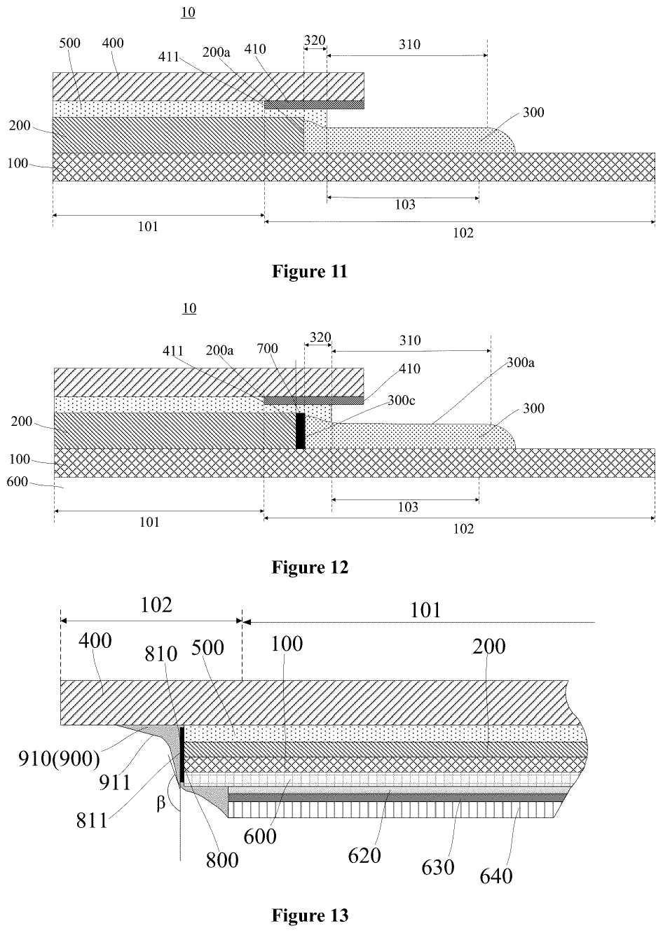

FIG. 11 is a schematic structural diagram of a display module according to another embodiment of the present disclosure. As shown in FIG. 11, in some embodiments, the display module 10 further includes a cover plate 400 and an optical adhesive layer 500, and the cover plate 400 is bond to a polarizer 200 via the optical adhesive layer 500. An ink layer 410 is disposed at a surface of the cover plate 400 facing the polarizer 200. The second protection portion 320 is in contact with the first side surface 200a of the polarizer 200, and the orthographic projection of the first side surface 200a on the display panel 100 is located within the orthographic projection of the ink layer 410 on the display panel 100.

The ink layer 410 is configured to serve as a screen which avoids light leakage via the non-active area 102 to improve a display effect. That is, an edge of the ink layer 410 close to the active area 101 may be regarded as a boundary dividing the active area 101 and the non-active area 102, and an edge of the ink layer 410 away from the active area 101 may be aligned with an edge of the cover plate 400.

The edge of the ink layer 410 close to the active area 101 may be defined as a first ink edge 411. In conventional technology, bubbles are apt to be formed in the optical adhesive layer 500 at positions close to a junction between the polarizer 200 and the protective adhesive layer 300, that is, close to the first side surface 200a. The ink layer 410 may further be configured to occlude the bubbles. In order to improve an effect of the occlusion, a distance between the first ink edge 411 and the first side surface 200a of the polarizer 200 along the direction pointing from the polarizer 200 to the protective adhesive layer 300 may be large. Hence, a dimension of the ink layer 410 along the direction pointing from the polarizer 200 to the protective adhesive layer 300 is large, which hinders meeting the requirement on the narrow bezel of display module 10.

In comparison, herein bubbles are less likely to be formed in the optical adhesive layer 500 between the cover plate 400 and the polarizer 200 of the display module 10, because the second protection portion 320 is configured to be not higher than the surface of the polarizer 200. On such basis, the first ink edge 411 can be moved by a certain distance toward the edge of the cover plate 400. For example, he first ink edge 411 may be moved outward by 60 μm, 50 μm, or the like, toward the edge of the cover plate 400. In one embodiment, the orthographic projection of the first side surface 200a on the display panel 100 is located within the orthographic projection of the ink layer 410 on the display panel 100, and the occlusion effect of the ink layer 410 is guaranteed. In one embodiment, the dimension of the ink layer 410 in the direction pointing from the polarizer 200 to the protective adhesive layer 300 can be reduced, and the bezel of the display module 10 can be narrower.

FIG. 12 is a schematic diagram of a display module according to another embodiment of the present disclosure. As shown in FIG. 12, in some embodiments, the display module 10 further includes the cover plate 400 and the optical adhesive layer 500, and the cover plate 400 is bond to the polarizer 200 via the optical adhesive layer 500. The ink layer 410 is disposed on the surface of the cover plate 400 facing the polarizer 200. An adhering layer 700 is disposed between the second protection portion 320 and the polarizer 200. The adhering layer 700 is in contact with the first side surface 200a of the polarizer 200, and the second protection portion 320 is in contact with the adhering layer 700 via second surface 300c of the second portion 300c. An orthographic projection of the second surface 300c on the display panel 100 is located within the orthographic projection of the ink layer 410 on the display panel 100.

The display module 10 as shown in FIG. 12 is different from that as shown in FIG. 11 in that the adhering layer 700 is provided. That is, on a basis of addressing the bubbles formed in the optical adhesive layer 500, the first ink edge 411 may be moved toward the edge of the cover plate 400 by a certain distance, for example, 60 μm or 50 μm. In one embodiment, the orthographic projection of the first side surface 200a on the display panel 100 is located within the orthographic projection of the ink layer 410 on the display panel 100, and the occlusion effect of the ink layer 410 is guaranteed. In one embodiment, the dimension of the ink layer 410 in the direction pointing from the polarizer 200 to the protective adhesive layer 300 can be reduced, and the bezel of the display module 10 can be narrower.

Another display module 10 is provided according to embodiments of the present disclosure. Reference is made to FIG. 13. The display module 10 includes a display panel 100, a cover plate 400, an adhering layer 800, and a sealant layer 900. The display panel 100 has a first side and a second side that are opposite to each other. The display panel 100 includes an active area 101 and a non-active area 102. The cover plate 400 is arranged at the first side of the display panel 100, and an edge of the cover plate 400 exceeds an edge of the display panel 100 when viewed in a direction perpendicular to the display panel. The adhering layer 800 includes a first adhering sub-layer 810, and the first adhering sub-layer 810 covers at least a side surface at the edge of the display panel 100. The sealant layer 900 includes a first sealant sub-layer 910, and the first sealant sub-layer 910 covers the first adhering sub-layer 810 and covers a surface, which is close to the display panel 100, of an edge of the cover plate 400. Surface energy of the sealant layer 900 is greater than or equal to surface energy of the adhering layer 800.

The display module 10 as shown in FIG. 13 differ from the foregoing display modules 10, e.g., as shown in FIG. 1, in following aspects. First, the adhering layer 800 is coated at a different position from that of the adhering layer 700. In this embodiment, the adhering layer 800 includes the first adhering sub-layer 810, and at least the part of the first adhering sub-layer 810 covers the edge of the display panel 100. Second, the sealant layer 900 is provided in this embodiment to seal edges of the display module 10.

In conventional technology, a sealant may be provided at side surface of a display module to improve protection on the whole module and prevent perspiration alkali and grease from invading into the module. A large amount of the sealant may provide good sealing but occupies a large space after being cured, which hinders implementation of the narrow bezel. A little amount of the sealant may deteriorate a sealing effect.

Herein at least the part of the first adhering sub-layer 810 covers the edge of the display panel 100, the first sealant sub-layer 910 of the sealant layer 900 covers the first adhering sub-layer 810 and the surface, which is close to of the display panel 100, of the edge portion of the cover plate 400, and the surface energy of the sealant layer 900 is greater than or equal to the surface energy of the adhering layer 800. In one embodiment, a good wetting effect is achieved between the first sealant sub-layer 910 and the first adhering sub-layer 810, and the first sealant sub-layer 910 in the liquid phase is capable to extend along the surface of the first adhering sub-layer 810, and the first sealant sub-layer 910 is capable to cover a large area after being cured. An amount of the sealant layer can be reduced while ensuring a sealing effect at a peripheral of the display module 10. Costs of the manufacture can be reduced while achieving the narrow bezel.

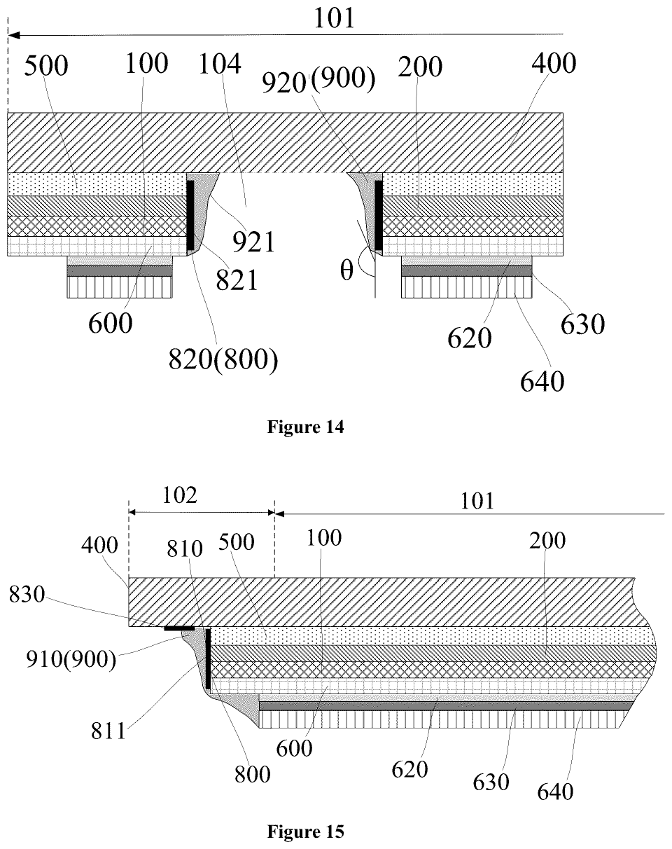

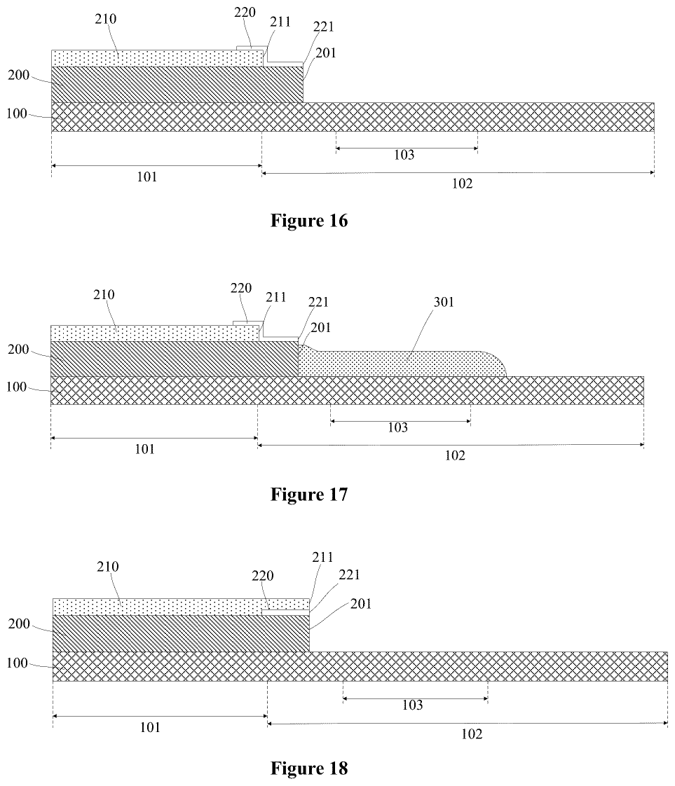

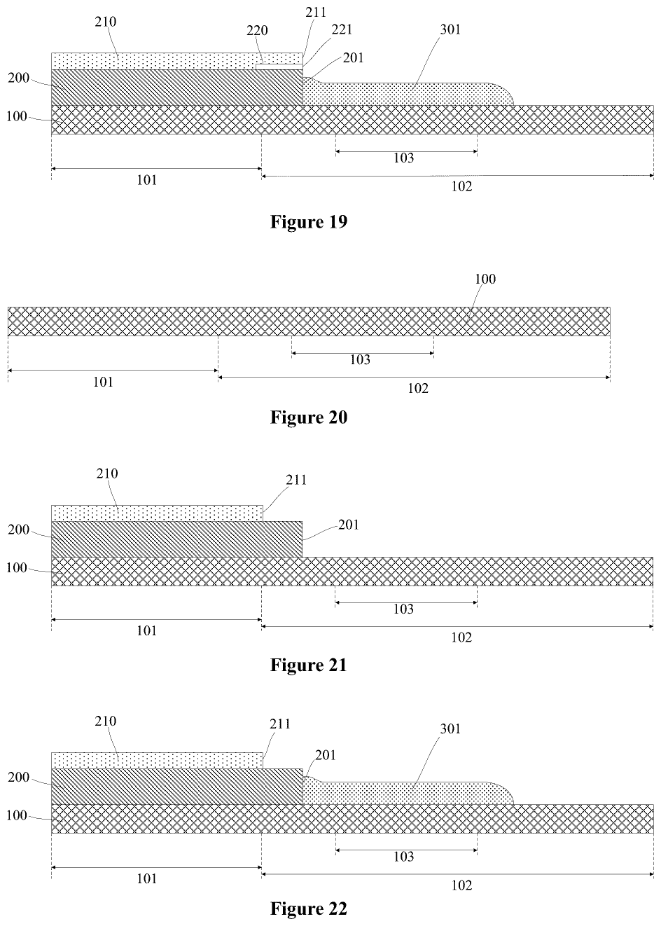

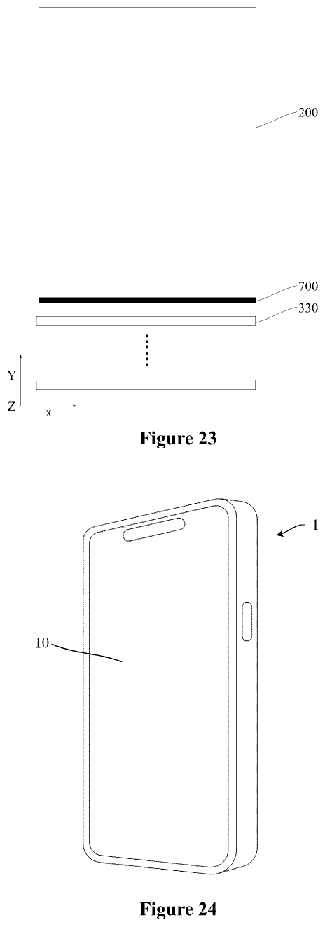

Reference is made to FIG. 14. In some embodiments, the display module 10 further includes a light-transmitting via hole 104 in the active area 101, and the light-transmitting via hole 104 runs from the second side of the display panel 100 to a surface of the cover plate 400 facing the display panel 100. The adhering layer 800 further includes a second adhering sub-layer 820, and the second adhering sub-layer 820 covers at least a sidewall of the light-transmitting via hole 104. The sealant layer 900 further includes a second sealant sub-layer 920, and the second sealant sub-layer 920 covers the second adhering sub-layer 820 and extends to a surface, which is close to the sidewall of the light-transmitting via hole 104, of the cover plate 400.

Herein the display module 10 may further include the light-transmitting via hole 104 in the active area 101. The light-transmitting via hole 104 in the active area 10 may be configured for installing an under-screen camera, a light sensor, a distance sensor, a depth sensor, an iris recognition sensor, an infrared sensor, or the like, which is not limited herein. The adhering layer 800 further includes the second adhering sub-layer 820, and the sealant layer 900 further includes the second sealant sub-layer 920. The second adhering sub-layer 820 covers at least the sidewall of the light-transmitting via hole 104, and the second sealant sub-layer 920 covers the second adhering sub-layer 820 and extends to the surface, which is close to the sidewall of the light-transmitting via hole 104, of the cover plate 400. Moreover, the surface energy of the sealant layer 900 is greater than or equal to the surface energy of the adhering layer 800. In one embodiment, a good wetting effect is achieved between the second sealant sub-layer 920 and the second adhering sub-layer 820, and the second sealant sub-layer 920 in the liquid phase is capable to extend along the surface of the second adhering sub-layer 820, and the second sealant sub-layer 920 covers a large area after being cured. Hence, the sidewall of the light-transmitting via hole 104 can be sealed with a small amount of the sealant layer. In one embodiment, costs of the manufacture can be reduced. In one embodiment, the second sealant sub-layer 920 has less occlusion on the light transmitting via hole 104, and hence light transmittance is improved at the light-transmitting via hole 104.

Reference is made to FIGS. 13 and 14. In some embodiments, the display module 10 further includes a polarizer 200 and an optical adhesive layer 500 that is between the display panel 100 and the cover plate 400, and a back plate 600 is disposed at the second side of the display panel 100. The display module 10 may further include a grid adhesive layer 620, a foam buffer layer 630, and a heat dissipation copper foil 640, and the like, which are sequentially at a side of the back plate 600 away from the display panel 100. In an embodiment, the light-transmitting via hole 104 runs through the back plate 600, the grid adhesive layer 620, the foam buffer layer 630, and the heat dissipation copper foil 640, and other film layers (if any).

In some embodiments, the ratio of the surface energy of the first adhering sub-layer 810 to the surface energy of the sealant layer 900 is greater than 0.6 and less than or equal to 1. That is, a relationship between the surface energy of the first sub-attachment layer 810 and the surface energy of the sealant layer 900 is limited. When the ratio of the surface energy of the first sub-attachment layer 810 to the surface energy of the sealant layer 900 is greater than 0.6 and less than or equal to 1, the sealant layer 900 covers an appropriate area after being cured, which improving sealing performances of the sealant layer 900 while ensuring small consumption of the sealant. In an embodiment, the ratio of the surface energy of the first adhering sub-layer 810 to the surface energy of the sealant layer 900 may be equal to 0.7, 0.75, 0.8, 0.9, 1, or the like.

Reference is further made to FIG. 13. In some embodiments, the first adhering sub-layer 810 has a first surface 811 away from the display panel 100, and the first sealant sub-layer 910 has a first sub-surface 911 away from the first adhering sub-layer 810. A second angle β is defined as an angle, which opens toward the backlight side of the display panel 100 and is between the tangent plane of the first sub-surface 911 and the first surface 811. The second angle β is greater than 120° and less than or equal to 180°.

That is, a shape of the first sub-surface 911 of the first sealant sub-layer 910 may be limited. The second angle β opens toward the backlight side of the display panel 100 and is located between the tangent plane of the first sub-surface 911 and the first surface 811 of the first adhering sub-layer 810. The tangent plane of the first sub-surface 911 refers to the tangent plane at any point on the first sub-surface 911. That is, there are multiple tangent planes of the first sub-surface 911, and the multiple tangent planes form multiple second angles β, respectively, with the first surface 811, and each second angle β is greater than 120° and less than or equal to 180°. Given the first sealant sub-layer 910 needs to seal the edge of the display module 10, herein the second angle β is controlled to be greater than 120° and less than or equal to 180°, which indicates that the first sealant sub-layer 910 in the liquid phase extends vertically along the first adhering sub-layer 810 and the first sealant sub-layer 910 after being cured may have extended beyond the first adhering sub-layer 810. In one embodiment, the edge of the display module 10 can be sealed with a small amount of the sealant, and the costs of the manufacture can be reduced while meeting the requirement on the narrow bezel. The above vertical direction with respect to the first adhering sub-layer 810 and the first sealant sub-layer 910 is parallel to the thickness direction of the display panel 100. In addition, the second angle β between a tangent plane at a certain position of the first sub-surface 911 and the first surface 811 being equal to 180° indicates that the tangent plane at such position is parallel to the first surface 811.

In some embodiments, the second angle β may range from 140° to 160°. As an example, the second angle β may range from 130° to 160°. As another example, the second angle β may range from 145° to 165°.

Reference is made to FIG. 15. In some embodiments, the adhering layer 800 further includes a third adhering sub-layer 830, and the third adhering sub-layer 830 covers the surface, which is close to the display panel 100, of the edge portion of the cover plate 400. The first sealant sub-layer 910 further covers a part of the third adhering sub-layer 830. A ratio of surface energy of the third adhering sub-layer 830 to the surface energy of the sealant layer 900 is greater than or equal to 0.4 and less than or equal to 0.6. For example, the ratio of the surface energy of the third adhering sub-layer 830 to the surface energy of the sealant layer 900 is equal to 0.4, 0.45, 0.5, 0.55, 0.6, or the like. Herein the adhering layer 800 further may further include the third adhering sub-layer 830, and the ratio of the surface energy of the third adhering sub-layer 830 to the surface energy of the sealant layer 900 is greater than or equal to 0.4 and less than or equal to 0.6. In one embodiment, when the sealant layer in the liquid phase contacts the third adhering sub-layer 830, it would not extend along the third adhering sub-layer 830, and thus the first sealant sub-layer 910 after being cured covers only the part of the third adhering sub-layer 830. In such case, the first sealant sub-layer 910 shrinks toward the display panel 100, and a width of an orthographic projection of the first sealant sub-layer 910 on the cover plate 400 is smaller than that in an embodiment as shown in FIG. 13. Hence, the bezel of the display module 10 can be further narrowed.

In some embodiments, the ratio of the surface energy of the second adhering sub-layer 820 to the surface energy of the sealant layer 900 is greater than 0.6 and less than or equal to 1. That is, a relationship between the surface energy of the second adhering sub-layer 820 and the surface energy of the sealant layer 900 is limited. When the ratio of the surface energy of the second adhering sub-layer 820 and the surface energy of the sealant layer 900 is greater than 0.6 and less than or equal to 1, a good wetting effect is achieved between the second sealant sub-layer 920 and the second adhering sub-layer 820, and the second sealant sub-layer 920 in the liquid phase is capable to extend along the surface of the second adhering sub-layer 820 to increase an area covered by the second sealant sub-layer 920 after being cured. In one embodiment, the sidewall of the light-transmitting via hole 104 can be sealed with a small amount of the sealant. In one embodiment, costs of manufacture are reduced. In one embodiment, the second sealant sub-layer 920 has less occlusion on the light-transmitting via hole 104, which improves light transmittance at the light-transmitting via hole 104. In an embodiment, the ratio of the surface energy of the second adhering sub-layer 820 to the surface energy of the sealant layer 900 is equal to 0.7, 0.75, 0.8, 0.9, 1, or the like.

Reference is further made to FIG. 14. In some embodiments, the second adhering sub-layer 820 has a second surface 821 away from the wall of the light-transmitting via hole 104, and the second sealant sub-layer 920 has a second sub-surface 921 away from the second adhering sub-layer 821. A third angle θ is defined as an angle, which opens toward the backlight side of the display panel 100 and is between the tangent plane of the second sub-surface 921 and the second surface 821. The third angle θ is greater than 120° and less than or equal to 180°.

That is, a shape of the second sub-surface 921 of the second sealant sub-layer 920 is defined. The third angle θ opens toward the backlight side of the display panel 100 and is located between the tangent plane of the second sub-surface 921 and the second surface 821 of the second adhering sub-layer 820. The tangent plane of the second sub-surface 921 refers to the tangent plane at any point on the second sub-surface 921. That is, there are multiple tangent planes of the second subsurface 921, the multiple tangent planes form multiple third angles θ, respectively, with the second surface 821, and each third angle θ is greater than 120° and less than or equal to 180°. Since the second sealant sub-layer 920 needs to seal the sidewall of the light-transmitting via hole 104 of the display module 10, the third angle θ controlled to be greater than 120° and less than or equal to 180° indicates that the second sealant sub-layer 920 extends vertically along the second adhering sub-layer 821, and the second sealant sub-layer 920 after being cured have extended beyond the second adhering sub-layer 821. In one embodiment, the sidewall of the light-transmitting via hole 104 of the display module 10 can be sealed with a small amount of the sealant. The costs of the manufacture is reduced, and the second sealant sub-layer 920 has less occlusion on the light-transmitting via hole 104, which further improves the light-transmittance at the light-transmitting via hole 104. The above vertical direction with respect to the second adhering sub-layer 821 and the second sealant sub-layer 920 is parallel to the thickness direction of the display panel 100. In addition, the third angle θ at a certain position of the second sub-surface 921 being equal to 180° indicates that the tangent plane at such position is parallel to the second surface 821.

In some embodiments, the third angle θ may range from 145° to 160°. As an example, the third angle θ may range from 130° to 150°. As another example, the third angle θ may range from 145° to 170°.

In one embodiment, a polarizer assembly is provided according to embodiments of the present disclosure. Reference is made to FIGS. 16 to 19. The polarizer assembly includes a polarizer 200, a protective film 210, and a non-wetting film 220. The protective film 210 is attached to an upper surface of the polarizer 200. The non-wetting film 220 is disposed on the upper surface of the polarizer 200 in adjacency of a first edge 201 of the polarizer 200. A second edge 221 of the non-wetting film 220 is aligned with the first edge 201 when viewed along a thickness direction of the polarizer 200.

Herein the polarizer assembly includes the polarizer 200, the protective film 210, and the non-wetting film 220. The non-wetting film 220 has the second edge 221 which is close to the first edge 201, and the second edge 221 is aligned with the first edge 201 of the polarizer 200 when viewed along the thickness direction. The polarizer assembly is attached to a display panel 100. In one embodiment, when coating the display panel 100 with a liquid protective adhesive 301 in a subsequent step, the protective adhesive 301 would not climb over the second edge 221 due to the non-wetting characteristics of the non-wetting coating layer 220. Such configuration ensures that the second protection portion 320 of the protective adhesive layer 300, which is formed after curing, would not be higher than the upper surface of the polarizer 200. That is, along a thickness direction of the display panel 100, the maximum dimension of the second protection portion 320 is not greater than a dimension of the polarizer 200. In one embodiment, when the optical adhesive layer 500 is attached in a subsequent step, attachment between the optical adhesive layer 500 and the upper surface of both the polarizer 200 and the protective adhesive layer 300 is good enough to avoid forming gaps. Hence, bubbles are less likely to be formed in the optical adhesive layer 500, and a yield of final products can be improved. In one embodiment, the second protection portion 320 would not climb higher than the polarizer 200, and a thickness of the second protection portion 320 can be adjusted to be more uniform. Hence, the average thickness of the second protection portion 320 and the average thickness of the first protection portion 310 can be more consistent, which facilitates improving thickness uniformity of the protective adhesive layer 300, and the distance between the bending-starting position of the bending area 103 and the polarizer 200 can be shortened. Moreover, the requirement on the narrow bezel of the display module 10 can be met. In one embodiment, the reduced thickness of the second protection portion 320 leads to small stress applied by the second protection portion 320 on the metal wires below. Hence, the metal wires are less likely to break in the bending area 103.

Reference is made to FIGS. 16 and 17. In an embodiment, the protective film 210 has a third edge 211 close to the first edge 201, and the third edge 211 is located right above the polarizer 200 and has a non-zero distance to the first edge 201. The non-wetting film 220 further covers the third edge 211 and a part of an upper surface of the protective film 210. Reference is made to FIGS. 18 and 19. In another embodiment, the non-wetting film 220 is disposed between the polarizer 200 and the protective film 210. The protective film 210 has a third edge 211 close to the first edge 201, and the third edge 211 is aligned with the second edge 221 when viewed along the thickness direction of the polarizer 200. In both the above two cases, the non-wetting characteristics of the non-wetting film 220 ensures that the protective adhesive layer 300 after being cured is not higher than the upper surface of the polarizer 200.

Moreover, in a case that the third side 211 is located right above the polarizer 200 and has a non-zero distance to the first edge 201, the non-zero distance may be greater than or equal to 0.05 mm and less than or equal to 2 mm.

In some embodiments, the thickness of the non-wetting film 220 is greater than or equal to 30 μm and less than or equal to 50 μm. The above thickness range facilitates both good accuracy in fabricating the non-wetting coating layer 220 and a non-excessive local thickness of the polarizer assembly.

In some embodiments, a contact angle of the non-wetting film 220 is greater than 90°. The contact angle refers to a tangent angle of a gas-liquid interface at an intersection among gas, liquid, and solid phases. A larger contact angle indicates better non-wetting characteristics of a liquid on a solid. The contact angle is related to the surface energy of objects, and the surface energy may be obtained through measuring the contact angle. Herein the contact angle of the non-wetting film 220 refers to the contact angle of the protective adhesive 301, which is in the liquid phase before being cured, dropped on the non-wetting film 220 that is placed horizontally. The contact angle of the non-wetting coating layer 220 is greater than 90°, which indicates that the liquid protective adhesive 301 does not climb onto the non-wetting coating layer 220. Hence, the thickness of the protective adhesive layer 300 after being cured is prevented from being larger than the thickness of the polarizer 200. In one embodiment, bubbles are less likely to be formed between the cover plate 400 and the polarizer 200, and the yield of final products can be improved. In one embodiment, the thickness of the second protection portion 320 can be adjusted to improve consistency between the average thickness of the second protection portion 320 and the average thickness of the first protection portion 310. That is, the thickness of the protective adhesive layer 300 is more uniform, and the distance between the bending-starting position of the bending area 103 and the polarizer 200 can be shortened, which facilitates meeting the requirement on the narrow bezel of the display module 10. In one embodiment, the stress applied by the second protection portion 320 on the metal wires below can be reduced, and hence the metal wires in the bending area 103 are less likely to break.

On a basis of the above concept, a method for manufacturing a display module is provided according to embodiments of the present disclosure. FIG. 20 is a schematic diagram of providing a display panel in a method for manufacturing a display module according to an embodiment of the present disclosure. FIG. 21 is a schematic diagram of pasting a polarizer assembly on a display panel in a method for manufacturing a display module according to an embodiment of the present disclosure. FIG. 22 is a schematic diagram of coating a protective adhesive on a display panel in a method for manufacturing a display module according to an embodiment of the present disclosure. As shown in FIGS. 20 to 22, the method includes steps S110 to S150.

In step S110, a display panel 100 is provided. The display panel 100 includes an active area 101 and a non-active area 102, and the non-active area 102 includes a bending area 103. Reference may be made to FIG. 1.

In step S120, a polarizer assembly is provided. The polarizer assembly includes a polarizer 200 and a protective film 210 that is attached to an upper surface the polarizer 200. The polarizer 200 has a first edge 201. The protective film 210 has a third edge 211 close to the first edge 201, and the third edge 211 is located right above the polarizer 200 and has a non-zero distance to the first edge 201.

In step S130, the polarizer assembly is attached to the display panel 100. After the attachment, the polarizer 200 covers the active area, and the first edge 201 is close to the bending area 103.

In step S140, the display panel 100 is coated with a liquid protective adhesive 301. After the coating, the protective adhesive 301 covers the bending area 103 and is in contact with the polarizer 200. An upper surface of the liquid protective adhesive 301 is not higher than the upper surface of polarizer 200. The liquid protective adhesive 301 is then cured to form the protective adhesive layer 300.

In step S150, the protective film 210 is removed.

Herein when manufacturing the display module 10, the third edge 211 of the protective film 210 in the polarizer assembly is located right above the polarizer 200 and has a non-zero distance to the first edge 201 of the polarizer 200. In one embodiment, when coating the display panel 100 with the liquid protective adhesive 301, the third edge 211 of the protective film 210 is spaced form the liquid protective adhesive 301, and the protective adhesive 301 cannot contact the third edge 211. Hence, the protective adhesive 301 is not capable to climb onto the third edge 211 of the protective film 210. Such configuration ensures that the second protection portion 320 of the protective adhesive layer 300 after being cured is not higher than the upper surface of the polarizer 200.

In one embodiment, when the optical adhesive layer 500 is attached in a subsequent step, attachment between the optical adhesive layer 500 and the upper surface of both the polarizer 200 and the protective adhesive layer 300 is good enough to avoid forming gaps. Thus, bubbles are less likely to be formed in the optical adhesive layer 500, and the yield of final products can be improved.

In some embodiments, the non-zero distance between the third edge 211 of the protective film 210 and the first edge 201 of the polarizer 200 is greater than or equal to 0.05 mm and less than or equal to 2 mm. In a case that the non-zero distance is too small, it is still possible that the protective adhesive 301 climbs onto the third edge 21 when being coated on the display panel 100. In a case that the non-zero distance is too large, protection of the protective film 210 on the polarizer 200 is inevitably weakened. Herein the non-zero may be controlled to be greater than or equal to 0.05 mm and less than or equal to 2 mm, and the protective adhesive 301 coated on the display panel 100 cannot climb onto the third edge 211 of the protective film 210, and the protection of the protective film 210 on the polarizer 200 is not significantly affected.

On a basis of one of the foregoing concepts, another method for manufacturing a display module is provided according to embodiments of the present disclosure. FIG. 16 is a schematic diagram of pasting a polarizer assembly on a display panel in a method for manufacturing a display module according to an embodiment of the present disclosure. FIG. 17 is a schematic diagram of coating a protective adhesive on a display panel in a method for manufacturing a display module according to an embodiment of the present disclosure. FIG. 18 is a schematic diagram of pasting a polarizer assembly on a display panel in a method for manufacturing a display module according to another embodiment of the present disclosure. FIG. 19 is a schematic diagram of coating a protective adhesive on a display panel in a method for manufacturing a display module according to another embodiment of the present disclosure. As shown in FIGS. 16 to 19, the method includes steps S210 to S250.

In step S210, a display panel 100 is provided. The display panel 100 includes an active area 101 and a non-active area 102, and the non-active area 102 includes a bending area 103

In step S220, a polarizer assembly is provided. The polarizer assembly includes a polarizer 200, a protective film 210, and a non-wetting film 220. The protective film 210 is attached to an uppers surface of the polarizer 200. The polarizer 200 has a first edge 201. The non-wetting film 220 is disposed on the upper surface of the polarizer 200 in adjacency of the first edge 201. The non-wetting film 220 has a second edge 221 in adjacency of the first edge 201. The second edge 221 of the non-wetting film 220 is aligned with the first edge 201 of the polarizer 200 when viewed along a thickness direction of the polarizer 200.

In step S230, the polarizer assembly is attached to the display panel 100. After the attachment, the polarizer 200 covers the active area 101, and the first edge 201 is close to the bending area 103.

In step S240, the display panel 100 is coated with a liquid protective adhesive 301. After the coating, the protective adhesive 301 covers the bending area 103 and is in contact with the first edge 201 of the polarizer 200. An upper surface of the liquid protective adhesive 301 is not higher than the upper surface of polarizer 200. The liquid protective adhesive 301 is then cured to form the protective adhesive layer 300.

In step S250, the protective film 210 and the non-wetting film 220 are removed.

The non-wetting film 220 may be made of a hydrophobic material or an oleophobic material.

Herein when manufacturing the display module 10, the polarizer assembly includes the polarizer 200, the protective film 210 and the non-wetting film 220. The non-wetting film 220 has the second edge 221 in adjacency of the first edge 201, and the second edge 221 of the non-wetting film 220 is aligned with the first edge 201 of the polarizer 200 when viewed along the thickness direction. In one embodiment, when coating the display panel 100 with the liquid protective adhesive 301, the protective adhesive 301 does not climb onto the second edge 221 due to the non-wetting characteristics of the non-wetting coating layer 220. Such configuration ensures that the second protection portion 320 of the protective adhesive layer 300 after being cured is not higher than the upper surface of the polarizer 200.

In one embodiment, when the optical adhesive layer 500 is attached in a subsequent step, attachment between the optical adhesive layer 500 and the upper surface of both the polarizer 200 and the protective adhesive layer 300 is good enough to avoid forming gaps. Thus, bubbles are less likely to be formed in the optical adhesive layer 500, and the yield of final products can be improved.

Reference is made to FIG. 16 and FIG. 17. In one embodiment, the protective film 210 has a third edge 211 in adjacency of the first edge 201, and the third edge 211 is located direction above the polarizer 200 and has a non-zero distance to the first edge 201. The non-wetting film 220 further covers the third edge 211 and a part of an upper surface of the protective film 210. Reference is made to FIG. 18 and FIG. 19. In another embodiment, the non-wetting film 220 is disposed between the polarizer 200 and the protective film 210. The protective film 210 has a third edge 211 in adjacency of the first edge 201, and the third edge 211 of the protective film 210 is aligned with the second edge 221 of the non-wetting film 220 when viewed along the thickness direction. In both the above two cases, the non-wetting characteristics of the non-wetting film 220 ensures that the second protection portion 320 of the protective adhesive layer 300 after being cured is not higher than the upper surface of the polarizer 200.

Moreover, in a case that the third side 211 is located right above the polarizer 200 and has a non-zero distance to the first edge 201, the non-zero distance may be greater than or equal to 0.05 mm and less than or equal to 2 mm.

In some embodiments, the thickness of the non-wetting film 220 is greater than or equal to 30 μm and less than or equal to 50 μm. The above thickness range facilitates both good accuracy in fabricating the non-wetting coating layer 220 and a non-excessive local thickness of the polarizer assembly.

On a basis of one of the foregoing concepts, another method for manufacturing a display module is provided according to embodiments of the present disclosure. The method includes following steps.

A display panel 100 is provided. The display panel 100 includes an active area 101 and a non-active area 102, and the non-active area 102 includes a bending area 103.

A polarizer 200 is provided. The polarizer 200 has a first side surface 200a.

The polarizer 200 is attached to the display panel 100. After the attachment, the polarizer 200 covers the active area 101, and the first side surface 200a is in adjacency of the bending area 103.

An adhering layer 700 is provided on the first side surface 200a.

A protective adhesive layer 300 is provided on the display panel 100. The protective adhesive layer 300 covers at least a part of the bending area 103. The protective adhesive layer 300 is in contact with the adhering layer 700. Surface energy of the protective adhesive layer 300 is greater than surface energy of the adhering layer 700.

Herein when manufacturing the display module 10, the adhering layer 700 is provided to suppress, or even eliminate formation, of a steep slope in the protective adhesive layer 300. In one embodiment, bubbles are less likely to be formed, thickness uniformity of the protective adhesive layer 300 is improve, metal wires are better protected, and the requirement on the narrow bezel of the display module 10 is met.

Reference is made to FIG. 23. In some embodiments, the protective adhesive layer 300 is formed through curing multiple adhesive strips 330, which are arranged at intervals.

The adhesive strips 330 may be formed through dispensing adhesives. Each of the adhesive strips 330 may extend along a first direction X, and the first direction X is perpendicular to a direction Y pointing from the polarizer 200 toward the adhering layer 700 and perpendicular to a thickness direction Z of the display panel 100. The protective adhesive layer 300 formed through dispensing can reduce costs and simplify the manufacture of the protective adhesive layer 300.

Reference is further made to FIG. 23. In some embodiments, along the direction from the polarizer 200 to the adhering layer 700, a distance between the adhesive strip 330, which is closes to the adhering layer 700, and the adhering layer 700 is less than 0.3 mm. In one embodiment, the adhesive strips 330 are not too far away from the adhering layer 700. In one embodiment, the adhesive strip 330 closes to the adhering layer is capable to contact the adhesive layer 700 after being cured, and thus the protective adhesive layer 300 and the adhesive layer 700 are less likely to be detached from each other. In one embodiment, thickness of the adhesive layer is unform after the adhesive strips 330 are cured, and its maximum thickness is less than or equal to the thickness of the polarizer 200. Hence, bubbles are less likely to be formed, the bezel of the display module 10 can be narrowed, the protective adhesive layer 300 is less likely to be detached from other films, and the metal wires are less likely to break.

In some embodiments, a distance between two adjacent adhesive strips 330 is less than 0.3 mm. In one embodiment, the adjacent two adhesive strips 330 is not too far away from each other, and all the adhesive strips 330 can connect to form a whole protective adhesive layer 300 after being cured. Hence, the protective adhesive layer 300 is capable to protect the metal wires below well. In one embodiment, thickness of the protective adhesive layer 300 fabricated from the multiple adhesive strips 330 has uniform thickness after the curing. That is, the protective adhesive layer 300 is highly uniform in thickness, and the thickness of the protective adhesive layer 300 does not exceed the thickness of the polarizer 200. In one embodiment, bubbles are less likely to be formed, the bezel of the display module 10 can be narrowed, the protective adhesive layer 300 is less likely to be detached from other films, and the metal wires are less likely to break.

On a basis of the above concepts, a display apparatus 1 is provided according to embodiments of the present disclosure. The display apparatus 1 includes any foregoing display module 10.

The display apparatus 1 and the display module 10 are based on identical concepts. Therefore, the display apparatus 1 may have all the beneficial effects illustrated in the foregoing description concerning the display module 10. Details of the display apparatus 1 may refer to the description of the display module 10 and would not be repeated herein.

Herein the display apparatus 1 may be a mobile phone as shown in FIG. 24 or may be any electronic product having a display function. The display apparatus 1 may be, but is no limited to, a television, a notebook computer, a desktop display, a tablet computer, a digital camera, a smart bracelet, a smart glass, an in-vehicle display, an industrial control equipment, a medical display screen, a touch interactive terminal, and the like. A specific type of the display apparatus 1 is not limited herein.

The embodiments may be arbitrarily combined. Herein not all possible combinations of the features are illustrated for the sake of clarity and conciseness. However, these combinations fall within the scope of the present disclosure as long as there is no conflict.

The foregoing embodiments show only several implementations of the present disclosure. The embodiments are described specifically with details, and shall not be construed as a limitation to a protection scope of the present disclosure. Those skilled in the art may make variations and improvements on a basis of the embodiments without departing from a concept of the present disclosure. These variations and improvements fall within the protection scope of the present disclosure. The protection scope of the present disclosure is determined by the appended claims.

1. A display module, comprising:
a display panel, wherein a non-active area of the display panel comprises a bending area;
a polarizer, disposed at a first side of the display panel, wherein at least a part of the polarizer covers an active area of the display panel; and
a protective adhesive layer, disposed at the first side of the display panel, wherein the protective adhesive layer comprises a first protection portion and a second protection portion, the first protection portion covers at least a part of the bending area, and the second protection portion is located between the first protection portion and the polarizer;
wherein along a thickness direction of the display panel, a maximum dimension of the second protection portion is less than or equal to a dimension of the polarizer.

2. The display module according to claim 1, wherein:
along the thickness direction of the display panel, a second average dimension of the second protection portion is greater than a first average dimension of the first protection, and
a difference between the second average dimension and the first average dimension is less than or equal to 15% of the first average dimension.

3. The display module according to claim 2, wherein a difference between the maximum dimension of the second protection portion and the first average dimension is less than or equal to 20% of the first average dimension.

4. The display module according to claim 1, further comprising:
a back plate disposed at a second side of the display panel, wherein the second side is opposite to the first side;
wherein there is a first opening in the back plate, and an orthographic projection of the first opening on the display panel is located within an orthographic projection of the first protection portion on the display panel.

5. The display module according to claim 4, wherein the first protection portion comprises:
a first section connected to the second protection portion, and
a second section connected to the first section;
wherein an orthographic projection of the second section on the display panel is located within the orthographic projection of the first opening on the display panel, and an orthographic projection of the first section on the display panel overlaps with the orthographic projection of the first opening on the display panel overlaps; and
wherein along a direction pointing from the polarizer to the protective adhesive layer, a length of the first section is less than or equal to ⅓ of a length of the second section, and thickness uniformity of the second section is greater than or equal to 70%.

6. The display module according to claim 1, wherein:
a first surface of the protective adhesive layer faces away from the first side of the display panel, and a first side surface of the polarizer faces the second protection portion; and
a first angle, which opens toward a light-emission direction of the display panel and is between a tangent plane of the first surface at the second protection portion and the first side surface, is greater than or equal to 70° and less than or equal to 120°.

7. The display module according to claim 6, wherein the first angle is greater than or equal to 80° and less than or equal to 100°.

8. The display module according to claim 1, further comprising:
an adhering layer disposed at a first side surface of the polarizer facing the second protection portion, wherein the second protection portion is in contact with the adhering layer, and surface energy of the protective adhesive layer is greater than surface energy of the adhering layer.

9. The display module according to claim 8, wherein a ratio of the surface energy of the adhering layer to the surface energy of the protective adhesive layer is greater than or equal to 0.4 and less than or equal to 0.6.

10. The display module according to claim 8, wherein:
a second surface of the second protection portion is in contact with the adhering layer; and
a difference between the maximum dimension of the second protection portion and a length of the second surface along the thickness direction is less than or equal to 20% of the length of the adhering layer.

11. The display module according to claim 8, wherein:
a first surface of the protective adhesive layer faces away from the first side of the display panel, and a first side surface of the polarizer faces the second protection portion; and
a first angle, which opens toward a light-emission side of the display panel and is between any tangent plane of the first surface at the second protection portion and the first side surface, is greater than or equal to 80° and less than or equal to 100°.

12. The display module according to claim 8, wherein;
a dimension of the adhering layer along the thickness direction is less than or equal the dimension of the polarizer, and
the maximum dimension of the second protection portion is less than or equal to the dimension of the adhering layer.

13. The display module according to claim 1, wherein:
a minimum dimension of the protective adhesive layer along the thickness direction is greater than or equal to ⅓ of the dimension of the polarizer, and
a maximum dimension of the protective adhesive layer along the thickness direction is less than or equal to the dimension of the polarizer.

14. The display module according to claim 1, further comprising:
a cover plate, arranged at the first side of the display panel, wherein an edge of the cover plate exceeds an edge of the display panel when viewed in a direction perpendicular to the display panel;
an adhering layer, comprising a first adhering sub-layer, wherein the first adhering sub-layer covers at least a side surface at the edge of the display panel; and
a sealant layer, comprising a first sealant sub-layer, wherein the first sealant sub-layer covers the first adhering sub-layer and covers a surface, which is close to the display panel, of an edge portion of the cover plate, and surface energy of the sealant layer is greater than or equal to surface energy of the adhering layer.

15. The display module according to claim 14, further comprising:
a light-transmitting via hole in an active area of the display panel, wherein the light-transmitting via hole runs from a second side of the display panel to a surface of the cover plate facing the display panel, and the second side is opposite to the first side;
wherein the adhering layer further comprises a second adhering sub-layer, and the second adhering sub-layer covers at least a sidewall of the light-transmitting via hole; and
wherein the sealant layer further comprises a second sealant sub-layer, and the second sealant sub-layer covers the second adhering sub-layer and extends to the surface, which is in adjacency of the sidewall the light-transmitting via hole, of the cover plate.

16. The display module according to claim 15, wherein at least one of:
a ratio of surface energy of the first adhering sub-layer to the surface energy of the sealant layer is greater than 0.6 and less than or equal to 1; or
a ratio of surface energy of the second adhering sub-layer to the surface energy of the sealant layer is greater than 0.6 and less than or equal to 1.

17. The display module according to claim 14, wherein:
the adhering layer further comprises a third adhering sub-layer covering the surface, which is close to the display panel, of the edge portion of the cover plate,
wherein the first sealant sub-layer covers a part of the third adhering sub-layer, and a ratio of surface energy of the third adhering sub-layer to the surface energy of the sealant layer is greater than or equal to 0.4 and less than or equal to 0.6.

18. The display module according to claim 15, wherein at least one of:
a first surface of the first adhering sub-layer faces away from the display panel, a first sub-surface of the first sealant sub-layer faces away from the first adhering sub-layer, and a second angle, which opens toward a backlight side of the display panel and is between any tangent plane of the first sub-surface and the first surface, is greater than 120° and less than or equal to 180°; or
a second surface of the second adhering sub-layer faces away from the sidewall, a second sub-surface of the second sealant sub-layer faces away from the second adhering sub-layer, and a third angle, which opens toward a backlight side of the display panel and is between any tangent plane of the second sub-surface and the second surface, is greater than 120° and less than or equal to 180°.

19. A display apparatus, comprising a display module, wherein:
a display panel, wherein a non-active area of the display panel comprises a bending area;
a polarizer, disposed at a first side of the display panel, wherein at least a part of the polarizer covers an active area of the display panel; and
a protective adhesive layer, disposed at the first side of the display panel, wherein the protective adhesive layer comprises a first protection portion and a second protection portion, the first protection portion covers at least a part of the bending area, and the second protection portion is located between the first protection portion and the polarizer;
wherein along a thickness direction of the display panel, a maximum dimension of the second protection portion is less than or equal to a dimension of the polarizer.
